(19) United States
(12) Patent Application Publication
(10) Pub. No.: US 2022/0099099 A1
(43) Pub. Date: Mar. 31, 2022

(54) IDENTIFICATION SIGNALS FOR FANS

(71) Applicant: Hewlett-Packard Development Company, L.P., Spring, TX (US)

(72) Inventors: Roger A. Pearson, Fort Collins, CO (US); Andrew L. Wiltzius, Fort Collins, CO (US)

(73) Assignee: Hewlett-Packard Development Company, L.P., Spring, TX (US)

(21) Appl. No.: 17/414,976

(22) PCT Filed: May 22, 2019
(86) PCT No.: PCT/US2019/033439

§ 371 Date: Jun. 17, 2021

(51) Int. Cl. F04D 27/00; H03K 7/08

(52) U.S. Cl. CPC F04D 27/004; H03K 7/08

(57) ABSTRACT

An example of an apparatus with an input connection to receive an input tachometer signal. The input tachometer signal may include a frequency to indicate a fan speed. A pulse width modulator may be coupled to the input connection and generate an output tachometer signal. The output tachometer signal may comprise an output frequency and a duty cycle. The output frequency may be based on the frequency of the input tachometer signal, and the duty cycle may indicate an identification corresponding to the fan.

### BACKGROUND

Fans may be used to assist in cooling systems. The fans may increase airflow and be used in conjunction with heat sinks or other heat dissipation devices. Fans may include power and ground connections, as well as a connection to indicate the speed of the fan.

### BRIEF DESCRIPTION OF THE DRAWINGS

Various examples will be described below referring to the following figures:

FIG. 1 shows an apparatus with a pulse width modulator coupled to an input connection in accordance with various examples;

FIG. 2 shows an apparatus with a fan blade coupled to a motor and a pulse generator in accordance with various examples;

FIG. 3 shows an apparatus with a fan, a pulse wave modulator, and a memory in accordance with various examples; and

FIG. 4 shows a method to measure a rotation speed of a fan and to generate a pulse train with a frequency and a duty cycle in accordance with various examples.

### DETAILED DESCRIPTION

Fans come in many different varieties. Even fans of the same general size and shape may have different fan speeds and capabilities. Fans may be replaceable, and the system may be optimized differently based on what types of fans are present in various fan slots. Automating the identification of different fans in a system may enable identification of an incorrect fan installation or provide an ability to optimize the system based on the fans present.

The tachometer signal of a fan may be used to provide an identification of the fan. The frequency of the tachometer signal indicates the rotational speed of the fan. The duty cycle or pulse width of the tachometer signal indicates an identification of the fan.

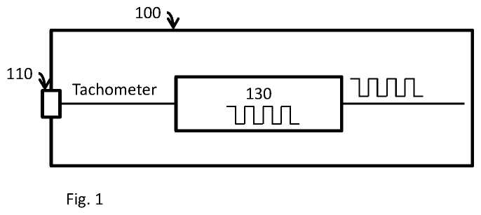

FIG. 1 shows an apparatus 100 with a pulse width modulator 130 coupled to an input connection 110 in accordance with various examples. The pulse width modulator 130 is coupled to the input connection 110 and is to receive an input tachometer signal. The pulse width modulator 130 is to output an output tachometer signal, where the duty cycle of the output tachometer signal provides an identification of the fan associated with the apparatus 100. The frequency of the output tachometer signal may be based on the frequency of the input tachometer signal.

In various examples, the apparatus 100 may be a distinct component from the fan. The apparatus 100 may be sold or distributed separately from a fan. The apparatus 100 may be placed in-line with the fan's tachometer line, receiving the tachometer signal from the fan and outputting a tachometer signal with identification information for use by an encompassing system. The apparatus 100 may also be placed in-line with the power and ground connections to the fan, which may provide power for the pulse width modulator 130 and associated circuitry. The apparatus 100 may be removed or replaced with another apparatus to provide a different identification for the fan.

In various examples, fan identification information may be encoded in the duty cycle of the tachometer signal. A 25% duty cycle may indicate one fan, a 50% duty cycle may indicate a second fan, and a 75% duty cycle may indicate a third fan. The number of different duty cycles used to identify different fans may depend on the accuracy of the signal generation and measurement devices.

In various examples, the identification signal may include an encoded signal, such as providing a serial encoding of binary-coded decimal. The identification signal may modify the duty cycle of a pulse wave to indicate a binary 1 or 0. A duty cycle of 50% may be used to indicate a start or a stop bit. A duty cycle of 25% may be used to indicate a binary 0, and a duty cycle of 75% may be used to indicate a binary 1. The identification signal may repeat. Using a start or stop bit may allow the identification signal to include an identification number encoded in an arbitrary number of bits. Thus one identification signal may use one start/stop bit and 4 numeric bits, while another identification signal may use one start/stop bit and 17 numeric bits. The start/stop bit may also enable the identification signal to leave off leading zeroes. The identification signal may modify the duty cycle of the pulse wave with successive pulses to provide the serial encoding.

In various examples, a base-3 or other encoding system may be used with a serial encoding. For example, in a base-3 system, a 20% duty cycle may indicate a start/stop bit, a 40% duty cycle may indicate a trinary 0, a 60% duty cycle may indicate a trinary 1, and an 80% duty cycle may indicate a trinary 2.

In various examples, the encoding of a bit or other base number system may cover multiple pulses. A start/stop bit may be sent for one, two, three, or another appropriate number of pulses of the pulse wave to allow sufficient signal for correct decoding of the signal. The number of pulses used may vary based on the frequency of the signal. For example, decoding may involve sending the pulse wave through a low-pass filter and performing an analog-to-digital conversion to determine the duty cycle. The decoding may expect a minimum amount of time that a duty cycle is maintained before switching to another duty cycle.

In various examples, the apparatus 100 may include the fan, such as by including a fan blade and a motor to operate the fan blade. The speed of the motor may be controlled by a voltage or current value provided via power and ground connections. Increasing the speed of the motor may cause the fan blade to spin more quickly and produce a tachometer signal of a higher frequency.

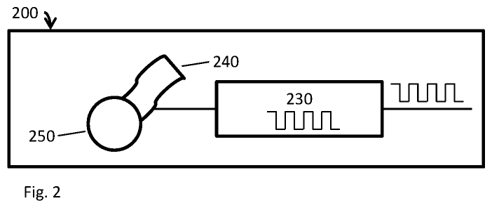

FIG. 2 shows an apparatus 200 with a fan blade 240 coupled to a motor 250 and a pulse generator 230 in accordance with various examples. Additional fan blades may be included in the apparatus 200.

The fan blade 240 is coupled to the motor 250 to allow the motor 250 to move the fan blade 240. The fan blade 240 may be coupled to rotate around the motor 250, with the motor in the epicenter of the fan blade's 240 movement. In various examples, the coupling may include the use of an axle or set of gears to allow the motor 250 to be in various different positions relative to the fan blade 240.

The fan blade 240 is coupled to the pulse generator 230 to provide an indication of the fan blade's 240 speed. In various examples, the fan blade 240 may be coupled to the pulse generator 230 to allow for rotation of the fan blade 240 while the pulse generator 230 remains stationary. The coupling may be by way of a rotary encoder to provide a signal indicating a rotation speed of the fan blade 240. The rotary encoder may use magnetic, optical, or other appropriate sensors to provide an indication of the rotational speed of the fan blade 240. Part of the rotary encoder may be attached to and rotate with the fan blade 240, while another part of the rotary encoder remains stationary relative to the fan blade 240. The rotary encoder may provide a pulse or other signal indicating when one of the two parts of the rotary encoder passes by the other. When additional fan blades are used, the rotary encoder may provide an indication as the various fan blades rotate past a certain location.

In various examples, the fan blade 240 may be coupled to the pulse generator 230 via the motor 250. A rotary encoder or other mechanism to indicate a rotational speed of the motor 250 may be provided to the pulse generator 230. This may also indicate a rotational speed of the fan blade 240, due to the coupling between the motor 250 and the fan blade 240.

In various examples, a selector may be used to allow selection of an identification signal to be generated by the pulse generator 230. The selector may include a slide switch, a knob, a toggle switch, or other mechanisms to allow an identification signal to be selected. Modifying the selector may change the duty cycle of the output tachometer signal generated by the pulse generator.

In various examples, the signal from the fan blade 240 or motor 250 to the pulse generator 230 may be a pulse train. The frequency of the pulse train provided to the pulse generator may indicate the rotation speed of the fan blade 240. The pulse generator 230 may modify the duty cycle of the received pulse train to encode the fan identification. The pulse generator 230 may use the frequency of the input pulse train to generate a different output pulse train that encodes the rotation speed of the fan blade 240 and the fan identification. The pulse generator 230 may measure the frequency of the input pulse train and generate an output pulse train of the appropriate frequency and duty cycle.

In various examples, the pulse generator may be partially integrated with the fan blade 240. For example, the fan blade 240 may include part of a rotary encoder. The rotary encoder may be designed to provide a distinctive duty cycle to provide an identification of the fan.

In various examples, the output of the pulse generator 230 may be a fixed voltage value. The fixed voltage value may be output when the fan speed is below a predetermined speed or is stopped. The fixed voltage value may be selected to provide an identification of the fan. When the identification of the fan is encoded in a constant duty cycle, the pulse train may be sent through a low-pass filter to produce a voltage value. The voltage value corresponds to the duty cycle and high and low voltage values used in the pulse train. For example, if the high value of the pulse train is 1 volt (V) and the low value of the pulse train is 0 V, a duty cycle of 50% may produce a 0.5 V voltage value when sent through a low-pass filter. A duty cycle of 25% may produce a 0.25 V voltage value. When the frequency of the signal to be generated by the pulse generator 230 is zero, providing a fixed voltage value may allow identification of the fan, even when the fan is stopped.

In various examples, the apparatus 200 may include a fan speed input. The fan speed input may receive a pulse-width-modulated (PWM) input signal to control the speed of the fan. The PWM input signal may be provided to the motor 250 to control the speed of the motor 250 and thus the speed of the fan blade 240.

In various examples, the identification of the fan may be encoded in a pulse width of the tachometer signal, independent of the frequency of the tachometer signal. One fan may be identified by a 1 microsecond pulse width of the tachometer signal. Another fan may be identified by a 2 microsecond pulse width of the tachometer signal. Pulse widths may also be used independent of the frequency to provide a binary or other base system coded decimal signal. For example, a 1 microsecond pulse width may signify a start/stop bit, a 2 microsecond pulse may signify a 0, a 3 microsecond pulse may signify a 1, and longer pulses may signify higher numbers in base number systems other than 2. In general, pulse width may be used in place of duty cycle to encode the identification of the fan.

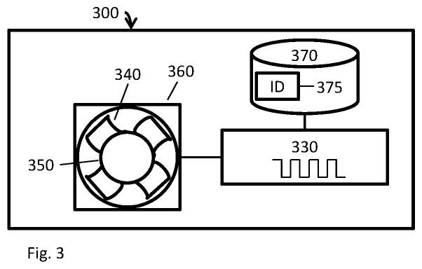

FIG. 3 shows an apparatus 300 with a fan 360, a pulse wave modulator 330, and a memory 370 in accordance with various examples. The fan 360 is coupled to the pulse wave modulator 330. The pulse wave modulator 330 is coupled to the memory 370. The memory 370 is to store an identification 375 corresponding to the fan 360. The fan 360 includes a motor 350 coupled to a fan blade 340. The motor 350 is to rotate the fan blade 340.

The pulse generator 330 may read the identification 375 from the memory 370. The pulse generator 330 may base the duty cycle of an output tachometer signal based on the rotational speed of the fan 360 and the identification 375. The frequency of the output tachometer signal may indicate the rotation speed of the fan 360. The duty cycle of the output tachometer signal may indicate the identification 375. The identification 375 may be encoded in the duty cycle of one pulse of the output tachometer signal or with varying duty cycles across multiple pulses of the output tachometer signal, such as for a serial transmission with a start/stop bit and a binary encoding of bits based on the duty cycle of a pulse.

In various examples, the memory 370 may be a programmable memory. The identification 375 may be modifiable. For example, the apparatus 300 may include an external access port to allow reading and writing to the memory 370. The external access port may be a physical port, such as a serial port, or a wireless port, such as via Bluetooth or WiFi.

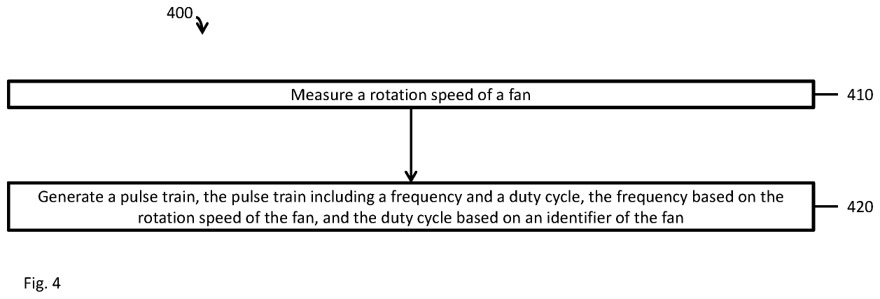

FIG. 4 shows a method 400 to measure a rotation speed of a fan and to generate a pulse train with a frequency and a duty cycle in accordance with various examples. The method 400 includes measuring a rotation speed of a fan (410). The method 400 includes generating a pulse train, the pulse train including a frequency and a duty cycle, the frequency based on the rotation speed of the fan, and the duty cycle based on an identifier of the fan (420).

In various examples the identifier may be stored in a memory. The identifier may be read from memory as part of generating the pulse train.

In various examples, the identifier may be specified by a knob or switch. The state of the knob or switch may be changed to modify the identifier provided in the pulse train. For example, a knob may be coupled to a variable resistor. The value of the resistor may affect the duty cycle of the pulse train. Thus, twisting the knob to different positions would cause a different duty cycle to be used, providing a different identifier for the fan.

In various examples, an intermediate pulse train may be generated as part of measuring the rotation speed of the fan. The intermediate pulse train may include the proper frequency data, but not have the proper duty cycle. The intermediate pulse train may be modified to have the proper duty cycle, or the intermediate pulse train may be used to control the frequency of the generated pulse train.

In various examples, a rotary encoder may be used to measure the rotation speed of the fan. A pulse wave modulator may use the signal from the rotary encoder to output a signal of the appropriate frequency, and use the identifier to control the duty cycle of the output signal.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An apparatus comprising:
an input connection to receive an input tachometer signal, the input tachometer signal including a frequency, the frequency to indicate a fan speed of a fan; and
a pulse width modulator coupled to the input connection, the pulse width modulator to generate an output tachometer signal, the output tachometer signal comprising an output frequency and a duty cycle, the output frequency based on the frequency of the input tachometer signal, and the duty cycle to indicate an identification corresponding to the fan.

2. The apparatus of claim 1 comprising a memory coupled to the pulse width modulator, the memory including a variable corresponding to the identification, the duty cycle based on the variable.

3. The apparatus of claim 1, wherein the duty cycle includes a first duty cycle percentage to encode a 0 value and a second duty cycle percentage to encode a 1 value, the output tachometer signal indicating the identification via a serial transmission of a code using the first duty cycle percentage and the second duty cycle percentage.

4. The apparatus of claim 3, wherein the code includes a binary-coded decimal value corresponding to the identification.

5. The apparatus of claim 1 comprising:
a fan blade; and
a motor to rotate the fan blade, a rotation speed of the motor based on a voltage of an input power.

6. An apparatus comprising:
a fan blade of a fan;
a motor coupled to the fan blade, the motor to rotate the fan blade; and
a pulse generator coupled to the fan blade, the pulse generator to generate a pulse train, the pulse train including a frequency and a pulse width, the frequency to indicate a rotation speed of the fan blade, the pulse width to indicate an identification corresponding to the fan.

7. The apparatus of claim 6 comprising an identification selector coupled to the pulse generator, the identification selector to store the identification.

8. The apparatus of claim 6 comprising a rotary encoder coupled to the fan blade and the pulse generator, the rotary encoder to measure the rotation speed of the fan blade.

9. The apparatus of claim 6 comprising a fan speed input, the fan speed input to receive a pulse-width-modulated signal, the motor to rotate the fan blade based on the pulse-width modulated signal.

10. The apparatus of claim 6, wherein the pulse generator is to provide a voltage value when the rotation speed is below a predetermined value.

11. A method comprising:
measuring a rotation speed of a fan; and
generating a pulse train, the pulse train including a frequency and a duty cycle, the frequency based on the rotation speed of the fan, and the duty cycle based on an identifier of the fan.

12. The method of claim 11 comprising reading the identifier from a memory.

13. The method of claim 11 comprising changing the identifier.

14. The method of claim 11, wherein the measurement of the rotation speed includes generating a second pulse train, the second pulse train including a second frequency, the second frequency based on the rotation speed, and the generation of the pulse train includes modifying the duty cycle of the second pulse train based on the identifier.

15. The method of claim 11 comprising performing the measurement via a rotary encoder, and performing the generation via a pulse generator coupled to the rotary encoder.
